(19) United States
(12) Patent Application Publication
(10) Pub. No.: US 2024/0220676 A1
(43) Pub. Date: Jul. 4, 2024

(54) SIMULATION OF LIDAR TRANSMISSION THROUGH A TRANSPARENT MATERIAL

(71) Applicant: GM Cruise Holdings LLC, San Francisco, CA (US)

(72) Inventors: Amin Aghaei, Fremont, CA (US); Xin Jiang, San Jose, CA (US)

(21) Appl. No.: 18/092,910

(22) Filed: Jan. 3, 2023

(51) Int. Cl. G06F 30/20

(52) U.S. Cl. CPC G06F 30/20

(57) ABSTRACT

Systems and techniques are provided for simulating a Light Detection and Ranging (LiDAR) transmission through at least partially transparent material. An example method can include receiving, within a simulation environment for an autonomous vehicle (AV), an angle of incidence that is formed between a simulated transmission from a simulated LiDAR sensor associated with the AV and a simulated at least partially transparent surface; determining, based on the angle of incidence, a probability of detecting at least one LiDAR return corresponding to a reflection of the simulated transmission from the simulated at least partially transparent surface; and generating simulated LiDAR perception data corresponding to the reflection of the simulated transmission from the simulated at least partially transparent surface based on a comparison between the probability and a target number, wherein the simulated LiDAR perception data includes a number of LiDAR returns.

### BACKGROUND

### 1. Technical Field

The present disclosure generally relates to autonomous vehicles, more specifically, to systems and techniques for simulating a Light Detection and Ranging (LiDAR) transmission through a transparent material.

### 2. Introduction

An autonomous vehicle is a motorized vehicle that can navigate without a human driver. An exemplary autonomous vehicle can include various sensors, such as a camera sensor, a light detection and ranging (LiDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system. Typically, the sensors are mounted at fixed locations on the autonomous vehicles.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1 illustrates an example system environment that can be used to facilitate autonomous vehicle (AV) dispatch and operations, according to some aspects of the disclosed technology;

FIGS. 2A and 2B illustrate simulated LiDAR sensor systems for simulating LiDAR transmission through glass, according to some examples of the present disclosure;

FIGS. 3A and 3B illustrate example linear function models for determining a probability of LiDAR transmission through glass, according to some examples of the present disclosure;

FIGS. 4A, 4B, 4C, and 4D illustrate example waveforms of LiDAR returns, according to some examples of the present disclosure;

FIG. 5 illustrates an example of a process for simulating a LiDAR transmission through at least partially transparent material, according to some examples of the present disclosure; and

FIG. 6 illustrates an example processor-based system with which some aspects of the subject technology can be implemented.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

Generally, sensors are integrated into a wide array of systems and electronic devices such as, for example, camera systems, mobile phones, autonomous systems (e.g., autonomous vehicles, unmanned aerial vehicles or drones, autonomous robots, etc.), computers, smart wearables, and many other devices. The sensors allow users to obtain sensor data that measures, describes, and/or depicts one or more aspects of a target such as an object, a scene, a person, and/or any other targets. For example, an image sensor can be used to capture frames (e.g., video frames and/or still pictures/images) depicting a target(s) from any electronic device equipped with an image sensor. As another example, a light ranging and detection (LiDAR) sensor can be used to determine ranges (variable distance) of one or more targets by directing a laser to a surface of an entity (e.g., a person, an object, a structure, an animal, etc.) and measuring the time for light reflected from the surface to return to the LiDAR (e.g., time to receive reflection corresponding to LiDAR transmission).

In a LiDAR system, a LiDAR sensor emits light waves (laser signals) from a laser into the environment. The signals bounce off the surface of surrounding objects and return to the LiDAR sensor. When a laser signal from a LiDAR sensor hits a transparent material such as glass, a portion of photons in the light signal can reflect off the surface while the other photons can pass through the transparent material. If an object is present behind the transparent material, the LiDAR sensor may receive reflection(s) not only from the transparent material but also from the object behind the transparent material. A LiDAR sensor processes the received reflection(s) (e.g., received waveform energy) and outputs the LiDAR return(s). The number of LiDAR returns can range between lower and upper bounds (e.g., from 0 to 3 LiDAR returns) depending on the presence or absence of an object behind a transparent material, a distance between the LiDAR sensor and the transparent material, and/or a distance between the transparent material and the object that may be present behind the transparent material. Further, the shape of peaks representing LiDAR returns in a waveform can depend on factors such as the reflectivity of the transparent material, reflectivity of any objects behind the transparent material, refractive indices, Visible Light Transmission (VLT) levels, thickness and/or curvature of the transparent material, a level of contamination on the transparent material, and/or an angle of incidence (e.g., between the beam and the transparent material and/or the beam and an object behind the transparent material). In other words, many factors associated with a transparent material (e.g., glass tint, contamination, curvature, thickness, etc.) can influence the LiDAR transmission. As follows, there exists a need for a single model that can simulate a wide variety of cases of LiDAR transmission through a transparent or translucent material (e.g., glass) that may be observed in a real-world environment.

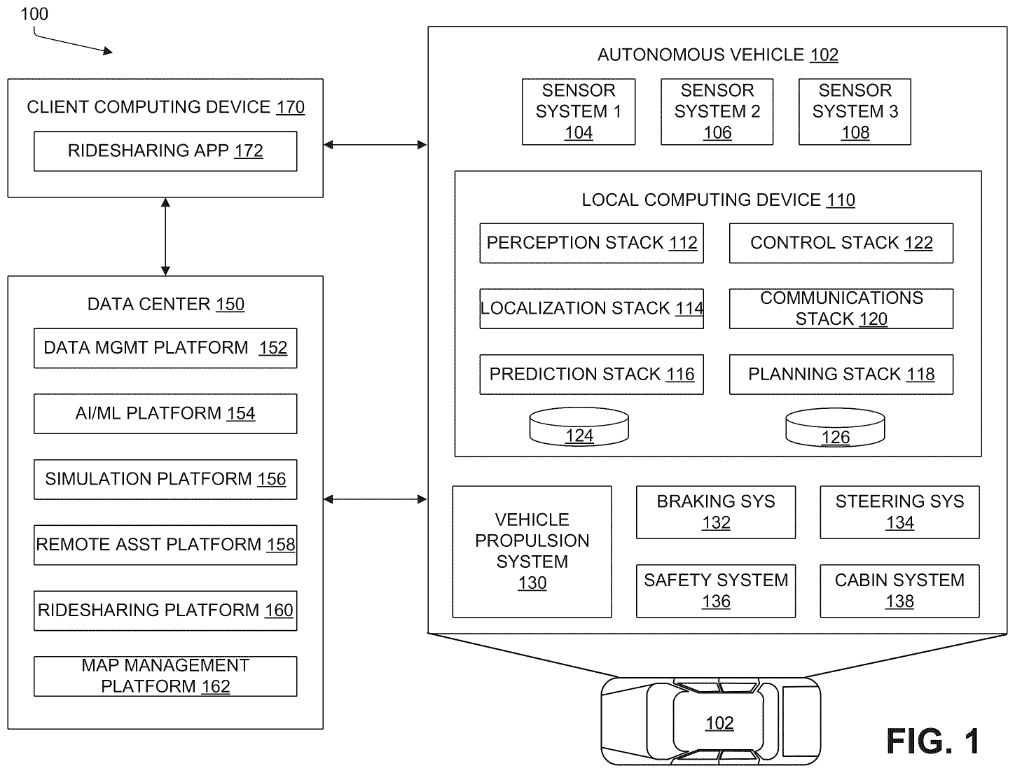

Described herein are systems, apparatuses, processes (also referred to as methods), and computer-readable media (collectively referred to as “systems and techniques”) for simulating a LiDAR transmission through at least partially transparent material (e.g., glass) in a simulated environment. More specifically, the systems and techniques described herein provide a probabilistic model for determining LiDAR returns from simulated LiDAR transmissions directed towards an at least partially transparent target such as glass in a simulated environment. Instead of having to individually simulate every possible scenario for different types of a transparent or translucent material, a tint level, a contamination level, a curvature of the transparent or translucent material, and properties of an object, the system and techniques described herein can provide synthetic data of which statistics can match with the statistics of real-world data. As follows, the systems and techniques can generate synthetic/simulated data that can be provided, as training data, to a machine learning model for a perception stack associated with an autonomous vehicle (AV) (e.g., the AV 102 as illustrated below with respect to FIG. 1). In some examples, the simulation of LiDAR transmission can be done through at least partially transparent material, translucent, fully transparent, or at least partially opaque material so that a degree or an amount of the light signals that bounce off from the surface can vary.

FIG. 1 is a diagram illustrating an example autonomous vehicle (AV) environment 100, according to some examples of the present disclosure. One of ordinary skill in the art will understand that, for the AV environment 100 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV environment 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by multiple sensor systems 104, 106, and 108. The sensor systems 104-108 can include one or more types of sensors and can be arranged about the AV 102. For instance, the sensor systems 104-108 can include Inertial Measurement Units (IMUs), cameras (e.g., still image cameras, video cameras, etc.), light sensors (e.g., LIDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LIDAR system, and the sensor system 108 can be a RADAR system. Other examples may include any other number and type of sensors.

The AV 102 can also include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some examples, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can include a local computing device 110 that is in communication with the sensor systems 104-108, the mechanical systems 130-138, the data center 150, and the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and an HD geospatial database 126, among other stacks and systems.

The perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can identify environmental uncertainties, such as where to look for moving objects, flag areas that may be obscured or blocked from view, and so forth. In some examples, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 114 can determine the AV's position and orientation (pose) using different methods from multiple systems (e.g., GPS, IMUs, cameras, LIDAR, RADAR, ultrasonic sensors, the HD geospatial database 126, etc.). For example, in some cases, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some examples, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV's steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include three-dimensional (3D) attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 124 can store raw AV data generated by the sensor systems 104-108, stacks 112-122, and other components of the AV 102 and/or data received by the AV 102 from remote systems (e.g., the data center 150, the client computing device 170, etc.). In some examples, the raw AV data can include HD LIDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can include a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and/or any other network. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, and a map management platform 162, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), and/or data having other characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, the map management platform 162, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from a cartography platform (e.g., map management platform 162); modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system such as, for example and without limitation, a server, desktop computer, laptop computer, tablet computer, smartphone, smart wearable device (e.g., smartwatch, smart eyeglasses or other Head-Mounted Display (HMD), smart ear pods, or other smart in-ear, on-ear, or over-ear device, etc.), gaming system, or any other computing device for accessing the ridesharing application 172. The client computing device 170 can be a customer's mobile computing device or a computing device integrated with the AV 102 (e.g., the local computing device 110). The ridesharing platform 160 can receive requests to pick up or drop off from the ridesharing application 172 and dispatch the AV 102 for the trip.

Map management platform 162 can provide a set of tools for the manipulation and management of geographic and spatial (geospatial) and related attribute data. The data management platform 152 can receive LIDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 162 can render base representations (e.g., tiles (2D), bounding volumes (3D), etc.) of the AV geospatial data to enable users to view, query, label, edit, and otherwise interact with the data. Map management platform 162 can manage workflows and tasks for operating on the AV geospatial data. Map management platform 162 can control access to the AV geospatial data, including granting or limiting access to the AV geospatial data based on user-based, role-based, group-based, task-based, and other attribute-based access control mechanisms. Map management platform 162 can provide version control for the AV geospatial data, such as to track specific changes that (human or machine) map editors have made to the data and to revert changes when necessary. Map management platform 162 can administer release management of the AV geospatial data, including distributing suitable iterations of the data to different users, computing devices, AVs, and other consumers of HD maps. Map management platform 162 can provide analytics regarding the AV geospatial data and related data, such as to generate insights relating to the throughput and quality of mapping tasks.

In some embodiments, the map viewing services of map management platform 162 can be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the client application 172 to enable passengers to view the AV 102 in transit en route to a pick-up or drop-off location, and so on.

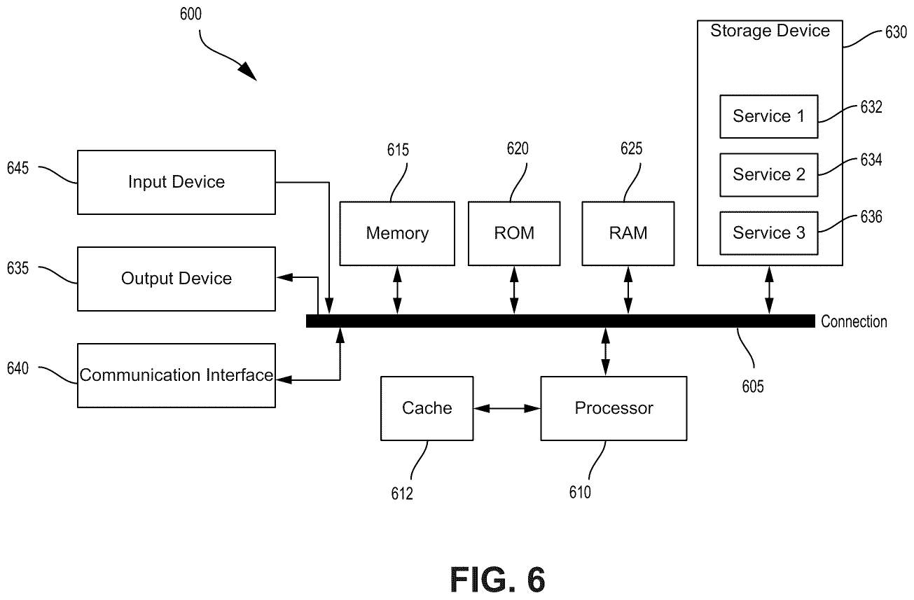

While the autonomous vehicle 102, the local computing device 110, and the autonomous vehicle environment 100 are shown to include certain systems and components, one of ordinary skill will appreciate that the autonomous vehicle 102, the local computing device 110, and/or the autonomous vehicle environment 100 can include more or fewer systems and/or components than those shown in FIG. 1. For example, the autonomous vehicle 102 can include other services than those shown in FIG. 1 and the local computing device 110 can also include, in some instances, one or more memory devices (e.g., RAM, ROM, cache, and/or the like), one or more network interfaces (e.g., wired and/or wireless communications interfaces and the like), and/or other hardware or processing devices that are not shown in FIG. 1. An illustrative example of a computing device and hardware components that can be implemented with the local computing device 110 is described below with respect to FIG. 6.

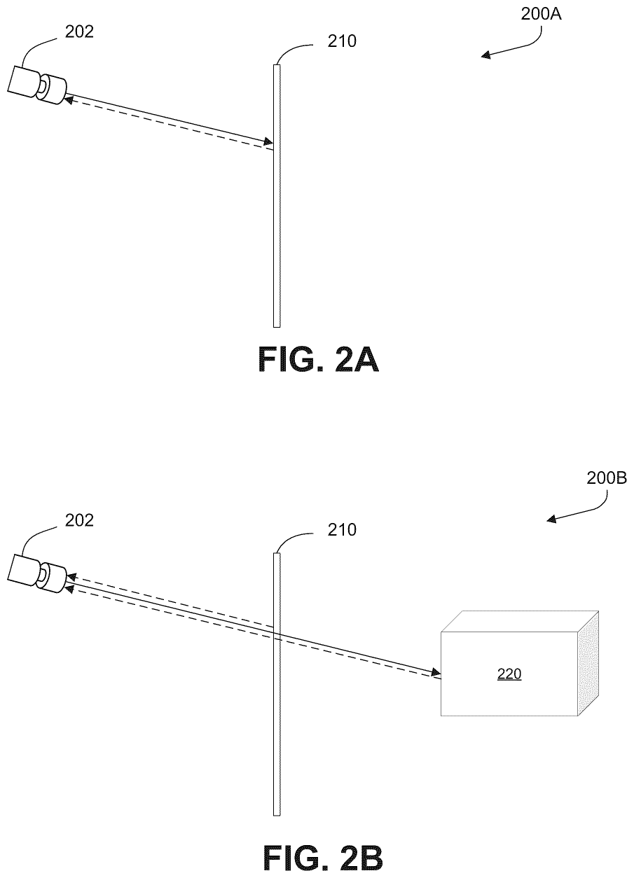

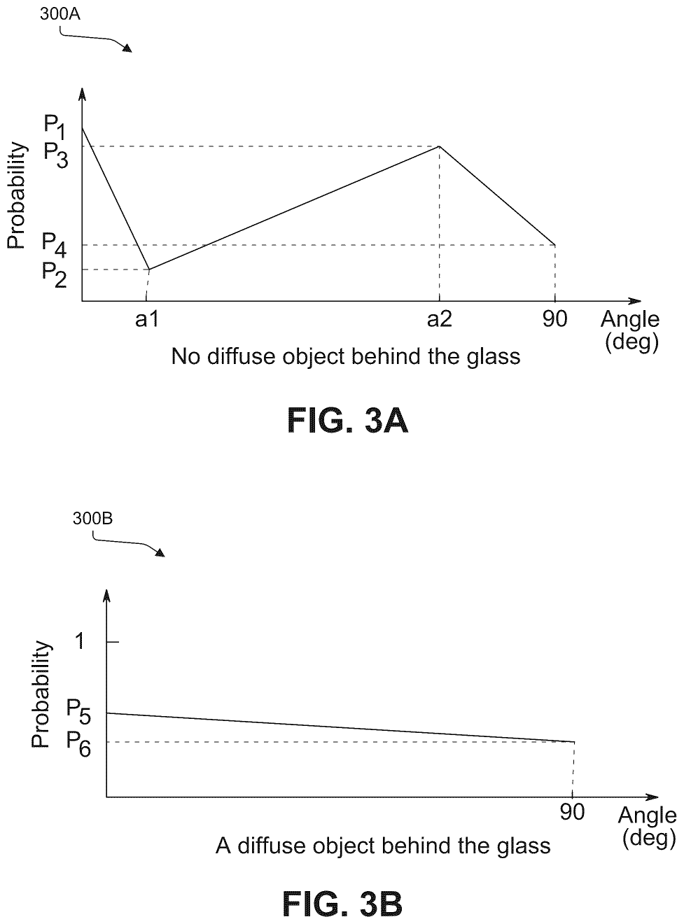

FIGS. 2A and 2B illustrate two scenarios that are related to simulated LiDAR sensor systems for simulating LiDAR transmission through glass. More specifically, FIG. 2A illustrates a simulation scenario 200A where transmission beams (e.g., laser signals) from a simulated LiDAR sensor 202 are directed to a simulated glass surface 210. The simulated LiDAR sensor 202 then receives reflection(s) (e.g., LiDAR return(s)) that are bounced off from the simulated glass surface 210. In some cases, because there is no simulated object located behind the simulated glass surface 210, a single return may be received corresponding to the reflection(s) from the simulated glass surface 210. In some examples, if the intensity (e.g., energy) of the return signal reflected from the simulated glass surface 210 is less than a threshold, the simulated LiDAR sensor 202 may disregard the LiDAR return. In some aspects, the probability that the intensity of the return signal is greater than the threshold can be determined by a piecewise linear function, as discussed further below in connection with FIG. 3A.

FIG. 2B illustrates simulation scenario 200B where a simulated object is placed behind the simulated glass surface 210. As follows, in the simulation scenario 200B, transmission beams (e.g., laser signals) from the simulated LiDAR sensor 202 can hit the simulated glass surface 210 and pass through the simulated glass surface 210 and may reach the simulated object 220. In this case, a LiDAR return can be 0 return (e.g., not enough energy returned from either the simulated glass surface 210 or the simulated object 220), 1 return corresponding to the reflection(s) from the simulated glass surface 210 or corresponding to the reflection(s) from the simulated object 220, and 2 returns where the first return corresponds to the reflection from the simulated glass surface 210 and the second return corresponding to the reflection from the simulated object 220. In some cases, the LiDAR return can be 0 return when the simulated glass surface 210 and the simulated object 220 are placed far from the simulated LiDAR sensor 202 that the transmission beams do not reach the simulated glass surface 210 or the simulated object 220. In some examples, the LiDAR return can be 0 when the simulated object 220 has a low reflectivity (e.g., black or opaque target/object). In some aspects, the LiDAR return can be 0 when the angle of incidence of the simulated glass surface 210 or the LiDAR sensor 202 is high.

FIGS. 3A and 3B illustrate example linear function models for determining a probability of LiDAR transmission through glass. FIG. 3A illustrates a piecewise linear function model 300A for a scenario where there is no simulated object behind a simulated glass surface (e.g., simulation scenario 200A in FIG. 2A). In other words, a probability of detecting a LiDAR return corresponding to a reflection of the simulated transmission from the simulated glass surface (e.g., the simulated glass surface 210) can be determined based on the piecewise linear function model 300A in a scenario where there is only a simulated glass surface that the simulated LiDAR transmission reaches and no other simulated object behind the simulated glass surface. As shown, the x-axis corresponds to an angle of incidence that is formed between a simulated transmission from a simulated LiDAR sensor and a simulated glass surface. The y-axis corresponds to the probability of receiving a reflection of the simulated LiDAR transmission from the simulated glass surface. As follows, based on a given angle of incidence, the probability can be determined based on the piecewise linear function model 300A in the case of the absence of a simulated object positioned behind the simulated glass surface (e.g., the simulation scenario 200A).

FIG. 3B illustrates a decreasing linear function model 300B for a scenario where there is a simulated object positioned behind a simulated glass surface (e.g., simulation scenario 200B in FIG. 2B). In other words, a probability of detecting a LiDAR return corresponding to a reflection of the simulated transmission from the simulated glass surface (e.g., the simulated glass surface 210) can be determined based on the decreasing linear function model 300B in a scenario where there is a simulated object (e.g., the simulated object 220) positioned behind the simulated glass surface. As shown, the x-axis corresponds to an angle of incidence that is formed between a simulated transmission from a simulated LiDAR sensor and a simulated glass surface. The y-axis corresponds to the probability of receiving a reflection of the simulated LiDAR transmission from the simulated glass surface. As follows, based on a given angle of incidence, the probability can be determined based on the decreasing linear function model 300B in the case of the presence of a simulated object positioned behind the simulated glass surface (e.g., the simulation scenario 200B).

A linear function model of the present disclosure (e.g., the piecewise linear function model 300A and the decreasing linear function model 300B, as shown in FIGS. 3A and 3B respectively) can be used to simulate different cases at once on a statistical level, in which the simulation data can then be fed to a machine learning algorithm/model for training (e.g., associated with a perception stack for object detection/classification).

Further, parameters of the linear function model can be tuned to serve different cases (e.g., more tinted or contaminated glass or clear or brighter glass) so that a probabilistic distribution that better fits different types of cases can be used. For example, in order to simulate more tinted or contaminated glass surface, probability parameters P1 through P6 can be increased in the linear function model (e.g., the piecewise linear function model 300A and the decreasing linear function model 300B as shown in FIGS. 3A and 3B). The increased probability parameters P1 through P6 indicate that more points are hitting the glass surface. In another example, in order to simulate more clear or brighter glass surface, probability parameters P5 and P6 can be lowered. Because the glass surface is clear, the LiDAR transmission beams penetrate through the glass surface. As a result, the probability of hitting an object that may be potentially positioned behind the glass surface is increased. Further, depending on the clarity of the glass surface or how much LiDAR transmission beams reach the potential object behind the glass surface, the strongest LiDAR return can be from the reflection(s) from the potential object.

In a simulated environment, an angle of incidence that is formed between a simulated transmission from a simulated LiDAR sensor (e.g., the simulated LiDAR sensor 202) and a simulated glass surface (e.g., the simulated glass surface 210) is known. Based on the known value of the angle of incidence, a probability of detecting a LiDAR return corresponding to a reflection of the simulated transmission from the simulated glass surface can be determined based on the linear function model (e.g., the piecewise linear function model 300A in case of an absence of a simulated object behind the simulated glass surface or the decreasing linear function model 300B in case of a presence of a simulated object behind the simulated glass surface).

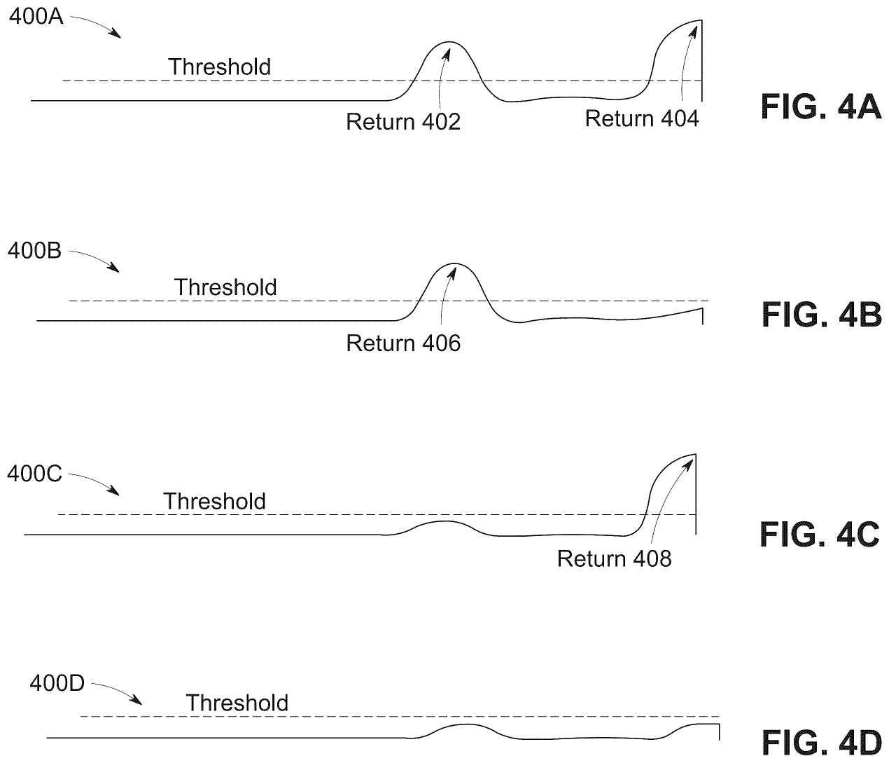

Once a probability value is determined based on the linear function model, a target number can be (randomly or semi-randomly) selected to further simulate LiDAR transmission. For example, a target number can be selected based on a uniform distribution, a simulation identifier, or a combination thereof. A target number can be compared against the probability value that is determined based on the linear function model. The comparison between the target number and the probability value can help determine different cases of simulated LiDAR returns, as discussed in detail below with respect to FIGS. 4A-4D.

FIGS. 4A-4D illustrate example waveforms of LiDAR returns based on simulation of LiDAR transmission through glass. In FIG. 4A, a waveform 400A shows two returns, return 402 (corresponding to a reflection of the simulated transmission from the simulated glass surface) and return 404 (corresponding to a reflection of the simulated transmission from the simulated object behind the simulated glass surface). For example, return 402 can correspond to a reflection from simulated glass surface 210 and return 404 can correspond to a reflection from simulated object 220.

In FIG. 4B, a waveform 400B shows one return that corresponds to a reflection of the simulated transmission from the simulated glass surface. For example, return 406 can correspond to a reflection from simulated glass surface 210. In FIG. 4C, a waveform 400C shows one return that corresponds to a reflection of the simulated transmission from the simulated object behind the simulated glass surface. For example, return 408 can correspond to a reflection from simulated object 220. In FIG. 4D, a waveform 400D shows no LiDAR return. That is, the simulated LiDAR sensor 202 did not detect any reflections or intensity (e.g., energy) of the reflected signal(s) that is less than a threshold value.

In some examples, the systems and techniques described herein can compare a probability value and a target number to determine different cases of simulated LiDAR returns, which are shown in the waveforms illustrated in FIGS. 4A-4D. In some aspects, in the case of an absence of a simulated object behind a simulated glass surface (similar to the scenario 200A in FIG. 2A), if a target number is lower than a probability value, the simulation can yield a single LiDAR return corresponding to a reflection of the simulated transmission from the simulated glass surface as shown in the waveform 400B of FIG. 4B. In some cases, if a target number is higher than a probability value, the simulation can yield zero LiDAR returns (e.g., there is no LiDAR return as shown in the waveform 400D of FIG. 4D).

In the case of a presence of a simulated object behind a simulated glass surface (similar to the scenario 200B in FIG. 2B), if a target number is lower than a probability value, the strongest LiDAR return would be from the simulated glass surface as the strongest return as shown in the waveform 400B of FIG. 4B with the second strongest return coming from the simulated object (e.g., a diffuse object).

Further, in case of a presence of a simulated object behind a simulated glass surface (similar to the scenario 200B in FIG. 2B), if a target number is higher than a probability value, there will be a single LiDAR return as shown in the waveform 400C of FIG. 4C depending on the distance between the simulated glass surface and the simulated object. In other words, if a target number is higher than a probability value and the distance between the simulated glass surface and the simulated object is below a distance threshold (e.g., 5 meters), there will be a single LiDAR return corresponding to a reflection of the simulated transmission from the simulated object. If the distance between the simulated glass surface (e.g., the simulated glass surface 210) and the simulated object (e.g., the simulated object 220 behind the simulated glass surface 210) is larger than a distance threshold (e.g., 5 meters), there will be no LiDAR return as shown in the waveform 400D of FIG. 4D. For example, if the distance between the simulated glass surface and the simulated object is too large, only a small signal from the simulated object will be reflected back to the simulated LiDAR sensor due to the energy loss between the simulated glass surface and the simulated object.

In some aspects, the LiDAR returns can be determined as shown in Table 1.

TABLE 1

| Simulated object | Target number | | | |
|---|---|---|---|---|
| (e.g., diffuse | is greater/ | | | |
| object) behind | lower than a | | | |
| simulated | probability | # of | Strongest | Second |
| glass surface | value | return(s) | return | strongest |
| Yes (e.g., | greater | 1 (e.g., | Simulated | N/A |
| FIG. 2B) | | FIG. 4C) | object | |
| | lower | 2 (e.g., | Simulated | Simulated |
| | | FIG. 4A) | glass surface | object |
| No (e.g., | greater | 0 (e.g., | N/A | N/A |
| FIG. 2A) | | FIG. 4D) | | |
| | lower | 1 (e.g., | Glass | N/A |
| | | FIG. 4B) | | |

While glass is used as an example of at least partially transparent material in FIGS. 2-4B, those skilled in the art will recognize that the present technology is not limited any particular material such as glass and can be implemented with at least partially transparent, translucent, or at least partially opaque material that may have a surface that passes through or bounces off the light signals from a LiDAR sensor.

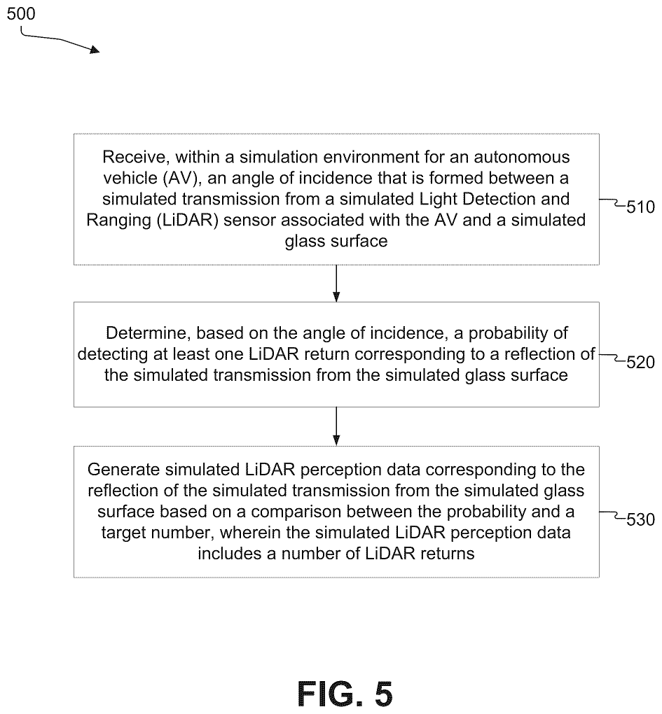

FIG. 5 is a flowchart illustrating an example process 500 for simulating a LiDAR transmission through at least partially transparent material. Although the example process 500 depicts a particular sequence of operations, the sequence may be altered without departing from the scope of the present disclosure. For example, some of the operations depicted may be performed in parallel or in a different sequence that does not materially affect the function of the process 500. In other examples, different components of an example device or system that implements the process 500 may perform functions at substantially the same time or in a specific sequence.

At block 510, the process 500 includes receiving, within a simulation environment for an AV, an angle of incidence that is formed between a simulated transmission from a simulated LiDAR sensor associated with the AV and a simulated at least partially transparent surface. For example, the systems and techniques described herein can receive, within a simulation environment for the AV 102, an angle of incidence that is formed between the simulated transmission from the simulated LiDAR sensor 202 associated with the AV 102 and the simulated glass surface 210.

At block 520, the process 500 includes determining, based on the angle of incidence, a probability of detecting at least one LiDAR return corresponding to a reflection of the simulated transmission from the simulated at least partially transparent surface. For example, the systems and techniques described herein can determine, based on the angle of incidence, a probability of detecting at least one LiDAR return corresponding to a reflection of the simulated transmission from the simulated glass surface 210.

At block 530, the process 500 includes generating simulated LiDAR perception data corresponding to the reflection of the simulated transmission from the simulated at least partially transparent surface based on a comparison between the probability and a target number, wherein the simulated LiDAR perception data includes a number of LiDAR returns. For example, the systems and techniques described herein can generate simulated LiDAR perception data corresponding to the reflection of the simulated transmission from the simulated glass surface 210 based on a comparison between the probability and a target number. The simulated LiDAR perception data can be used as training data for a machine learning algorithm/model of a perception stack associated with an AV (e.g., the AV 102 as illustrated in FIG. 1).

In some aspects, the target number can be selected based on various techniques. In some examples, the target number can be randomly selected based on a uniform distribution or any other mapped distribution (e.g., between 0 and 1) such as normal distribution, Cauchy, Laplace, etc. For example, for every LiDAR point that hits the simulated at least partially transparent surface, a target number is selected individually and independently based on the distribution. There are several ways for generating numbers from a distribution. In some cases, computer programming language compilers have several built-in random number generators. The random distribution code can also be made by any programmer or provided by third-party applications.

In some cases, the target number can be selected based on a simulation identifier associated with the simulated at least partially transparent surface. For example, in simulation, each simulated window can be assigned with a unique simulation identifier. The unique simulation identifier can be provided to a target number generator (e.g., a random number generator) before drawing a random number from the target number generator. As a result, a single target number can be used for the entire surface of the simulated glass throughout the simulation. As follows, all points on a given glass target can be compared with the same target number as provided in FIGS. 3A and 3B.

In some examples, the target number can be selected based on a combination of a uniform distribution and a simulation identifier associated with the simulated at least partially transparent surface. For example, a target number can be a weighted value that is obtained from a weighted function where a uniform distribution and a simulation identifier have respective predetermined weights.

In some examples, the process 500 includes identifying a simulated object (e.g., the simulated object 220) that is positioned behind the simulated at least partially transparent surface (e.g., the simulated glass surface 210). Further, the process 500 can include providing the angle of incidence to a decreasing linear function model (e.g., the decreasing linear function model 300B) to determine the probability of detecting at least one LiDAR return. For example, the decreasing linear function model 300B can provide the probability (e.g., on the y-axis) with a given angle of incidence (e.g., on the x-axis) when there is a simulated object is positioned behind the simulated at least partially transparent surface.

In some examples, the systems and techniques described herein can determine that the number of LiDAR returns is two based on the comparison between the probability and the target number. For example, a first LiDAR return 402 corresponds to the simulated glass surface 210 and a second LiDAR return 404 corresponds to the simulated object 220 as shown in the waveform 400A of FIG. 4A.

In some examples, the systems and techniques described herein can determine that the number of LiDAR returns is one based on the comparison between the probability and the target number. For example, the simulated LiDAR perception data includes a single LiDAR return corresponding to the simulated at least partially transparent surface (e.g., the simulated glass surface 210). As shown in the waveform 400B of FIG. 4B, the return 406 corresponds to the LiDAR return corresponding to the simulated glass surface 210. In another example, the simulated LiDAR perception data includes a single LiDAR return corresponding to the simulated object (e.g., the simulated object 220). As shown in the waveform 400C of FIG. 4C, the return 408 corresponds to the LiDAR return corresponding to the simulated object 220 that is positioned behind the simulated glass surface 210.

In some examples, the systems and techniques described herein can determine that the number of LiDAR returns is zero where a distance between the simulated object (e.g., the simulated object 220) and the simulated at least partially transparent surface (e.g., the simulated glass surface 210) exceeds a distance threshold value. Due to the energy loss between the simulated glass surface 210 and the simulated object 220, only a small signal from the simulated object 220 can be returned to the simulated LiDAR sensor, which results in zero LiDAR return.

In some aspects, the process 500 includes determining an absence of a simulated object that is positioned behind the simulated at least partially transparent surface. Further, the process 500 includes providing the angle of incidence to a piecewise linear function model (e.g., the piecewise linear function model 300A) to determine the probability of detecting at least one LiDAR return. For example, the piecewise linear function model 300A can provide the probability (e.g., on the y-axis) with a given angle of incidence (e.g., on the x-axis) when there is no simulated object positioned behind the simulated at least partially transparent surface.

In some examples, the systems and techniques described herein can determine that the number of LiDAR returns is zero based on the comparison between the probability and the target number. For example, if the target number is higher than the probability value, there is no reflection received at the simulated LiDAR sensor, which results in zero LiDAR return.

In some examples, the systems and techniques described herein can determine that the number of LiDAR returns is one based on the comparison between the probability and the target number (e.g., if the target number is above the probability value). For example, the simulated LiDAR perception data includes a single LiDAR return corresponding to the simulated glass surface 210.

FIG. 6 illustrates an example processor-based system with which some aspects of the subject technology can be implemented. For example, processor-based system 600 can be any computing device making up, or any component thereof in which the components of the system are in communication with each other using connection 605. Connection 605 can be a physical connection via a bus, or a direct connection into processor 610, such as in a chipset architecture. Connection 605 can also be a virtual connection, networked connection, or logical connection.

In some embodiments, computing system 600 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 600 includes at least one processing unit (Central Processing Unit (CPU) or processor) 610 and connection 605 that couples various system components including system memory 615, such as Read-Only Memory (ROM) 620 and Random-Access Memory (RAM) 625 to processor 610. Computing system 600 can include a cache of high-speed memory 612 connected directly with, in close proximity to, or integrated as part of processor 610.

Processor 610 can include any general-purpose processor and a hardware service or software service, such as services 632, 634, and 636 stored in storage device 630, configured to control processor 610 as well as a special-purpose processor where software instructions are incorporated into the actual processor design. Processor 610 may essentially be a completely self-contained computing system, containing multiple cores or processors, a bus, memory controller, cache, etc. A multi-core processor may be symmetric or asymmetric.

To enable user interaction, computing system 600 includes an input device 645, which can represent any number of input mechanisms, such as a microphone for speech, a touch-sensitive screen for gesture or graphical input, keyboard, mouse, motion input, speech, etc. Computing system 600 can also include output device 635, which can be one or more of a number of output mechanisms known to those of skill in the art. In some instances, multimodal systems can enable a user to provide multiple types of input/output to communicate with computing system 600. Computing system 600 can include communication interface 640, which can generally govern and manage the user input and system output. The communication interface may perform or facilitate receipt and/or transmission wired or wireless communications via wired and/or wireless transceivers, including those making use of an audio jack/plug, a microphone jack/plug, a Universal Serial Bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, Wireless Local Area Network (WLAN) signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 640 may also include one or more Global Navigation Satellite System (GNSS) receivers or transceivers that are used to determine a location of the computing system 600 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 630 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, Random-Access Memory (RAM), Atatic RAM (SRAM), Dynamic RAM (DRAM), Read-Only Memory (ROM), Programmable ROM (PROM), Erasable PROM (EPROM), Electrically Erasable PROM (EEPROM), flash EPROM (FLASHEPROM), cache memory (L1/L2/L3/L4/L5/L #), Resistive RAM (RRAM/ReRAM), Phase Change Memory (PCM), Spin Transfer Torque RAM (STT-RAM), another memory chip or cartridge, and/or a combination thereof.

Storage device 630 can include software services, servers, services, etc., that when the code that defines such software is executed by the processor 610, it causes the system 600 to perform a function. In some embodiments, a hardware service that performs a particular function can include the software component stored in a computer-readable medium in connection with the necessary hardware components, such as processor 610, connection 605, output device 635, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Illustrative examples of the disclosure include:
Aspect 1. A system comprising: a memory; and one or more processors coupled to the memory, the one or more processors being configured to: receive, within a simulation environment for an autonomous vehicle (AV), an angle of incidence that is formed between a simulated transmission from a simulated Light Detection and Ranging (LiDAR) sensor associated with the AV and a simulated at least partially transparent surface; determine, based on the angle of incidence, a probability of detecting at least one LiDAR return corresponding to a reflection of the simulated transmission from the simulated at least partially transparent surface; and generate simulated LiDAR perception data corresponding to the reflection of the simulated transmission from the simulated at least partially transparent surface based on a comparison between the probability and a target number, wherein the simulated LiDAR perception data includes a number of LiDAR returns.
Aspect 2. The system of Aspect 1, wherein the one or more processors are configured to: identify a simulated object that is positioned behind the simulated at least partially transparent surface; and provide the angle of incidence to a decreasing linear function model to determine the probability.
Aspect 3. The system of Aspect 2, wherein the one or more processors are configured to: determine that the number of LiDAR returns is two based on the comparison between the probability and the target number, wherein the simulated LiDAR perception data includes a first LiDAR return corresponding to the simulated at least partially transparent surface and a second LiDAR return corresponding to the simulated object.
Aspect 4. The system of Aspect 2, wherein the one or more processors are configured to: determine that the number of LiDAR returns is one based on the comparison between the probability and the target number, wherein the simulated LiDAR perception data includes a single LiDAR return corresponding to the simulated at least partially transparent surface.
Aspect 5. The system of Aspect 2, wherein the one or more processors are configured to: determine that the number of LiDAR returns is one based on the comparison between the probability and the target number, wherein the simulated LiDAR perception data includes a single LiDAR return corresponding to the simulated object.
Aspect 6. The system of Aspect 2, wherein the number of LiDAR returns is zero when a distance between the simulated object and the simulated at least partially transparent surface exceeds a distance threshold value.
Aspect 7. The system of any of Aspects 1 through 6, wherein the one or more processors are configured to: determine an absence of a simulated object that is positioned behind the simulated at least partially transparent surface; and provide the angle of incidence to a piecewise linear function model to determine the probability.
Aspect 8. The system of Aspect 7, wherein the one or more processors are configured to: determine that the number of LiDAR returns is zero based on the comparison between the probability and the target number.
Aspect 9. The system of Aspect 7, wherein the one or more processors are configured to: determine that the number of LiDAR returns is one based on the comparison between the probability and the target number, wherein the simulated LiDAR perception data includes a single LiDAR return corresponding to the simulated at least partially transparent surface.
Aspect 10. The system of any of Aspects 1 through 9, wherein the target number is randomly selected based on a uniform distribution.
Aspect 11. The system of any of Aspects 1 through 10, wherein the target number is selected based on a simulation identifier associated with the simulated at least partially transparent surface.
Aspect 12. The system of any of Aspects 1 through 11, wherein the target number is a weighted value based on a uniform distribution and a simulation identifier associated with the simulated at least partially transparent surface.
Aspect 13. A method comprising: receiving, within a simulation environment for a Light Detection and Ranging (LiDAR) sensor, an angle of incidence that is formed between a simulated transmission from a simulated LiDAR sensor and a simulated at least partially transparent surface; determining, based on the angle of incidence, a probability of detecting at least one LiDAR return corresponding to a reflection of the simulated transmission from the simulated at least partially transparent surface; and generating simulated LiDAR perception data corresponding to the reflection of the simulated transmission from the simulated at least partially transparent surface based on a comparison between the probability and a target number, wherein the simulated LiDAR perception data includes a number of LiDAR returns.
Aspect 14. The method of Aspect 13, further comprising: identifying a simulated object that is positioned behind the simulated at least partially transparent surface; and providing the angle of incidence to a decreasing linear function model to determine the probability.
Aspect 15. The method of Aspect 14, further comprising: determining that the number of LiDAR returns is two based on the comparison between the probability and the target number, wherein the simulated LiDAR perception data includes a first LiDAR return corresponding to the simulated at least partially transparent surface and a second LiDAR return corresponding to the simulated object.
Aspect 16. The method of Aspect 14, further comprising: determining that the number of LiDAR returns is one based on the comparison between the probability and the target number, wherein the simulated LiDAR perception data includes either a single LiDAR return corresponding to the simulated at least partially transparent surface or a single LiDAR return corresponding to the simulated object.
Aspect 17. The method of Aspect 14, wherein the number of LiDAR returns is zero when a distance between the simulated object and the simulated at least partially transparent surface exceeds a distance threshold value.
Aspect 18. The method of any of Aspects 13 through 17, further comprising: determining an absence of a simulated object that is positioned behind the simulated at least partially transparent surface; and providing the angle of incidence to a piecewise linear function model to determine the probability.
Aspect 19. The method of any of Aspects 13 through 18, the target number is selected based on at least one of a uniform distribution, a simulation identifier associated with the simulated at least partially transparent surface, and a combination thereof.
Aspect 20. A non-transitory computer-readable storage medium comprising at least one instruction for causing a computer or processor to: receive, within a simulation environment for Light Detection and Ranging (LiDAR) sensor, an angle of incidence that is formed between a simulated transmission from a simulated LiDAR sensor and a simulated at least partially transparent surface; determine, based on the angle of incidence, a probability of detecting at least one LiDAR return corresponding to a reflection of the simulated transmission from the simulated at least partially transparent surface; and generate simulated LiDAR perception data corresponding to the reflection of the simulated transmission from the simulated at least partially transparent surface based on a comparison between the probability and a target number, wherein the simulated LiDAR perception data includes a number of LiDAR returns.
Aspect 21. An autonomous vehicle comprising: a memory and one or more processors coupled to the memory, the one or more processors being configured to perform a method according to any of Aspects 13 to 19.
Aspect 22. A system comprising means for performing a method according to any of Aspects 13 to 19.

What is claimed is:

1. A system comprising:
a memory; and
one or more processors coupled to the memory, the one or more processors being configured to:
receive, within a simulation environment for an autonomous vehicle (AV), an angle of incidence that is formed between a simulated transmission from a simulated Light Detection and Ranging (LiDAR) sensor associated with the AV and a simulated at least partially transparent surface;
determine, based on the angle of incidence, a probability of detecting at least one LiDAR return corresponding to a reflection of the simulated transmission from the simulated at least partially transparent surface; and
generate simulated LiDAR perception data corresponding to the reflection of the simulated transmission from the simulated at least partially transparent surface based on a comparison between the probability and a target number, wherein the simulated LiDAR perception data includes a number of LiDAR returns.

2. The system of claim 1, wherein the one or more processors are configured to:
identify a simulated object that is positioned behind the simulated at least partially transparent surface; and
provide the angle of incidence to a decreasing linear function model to determine the probability.

3. The system of claim 2, wherein the one or more processors are configured to:
determine that the number of LiDAR returns is two based on the comparison between the probability and the target number, wherein the simulated LiDAR perception data includes a first LiDAR return corresponding to the simulated at least partially transparent surface and a second LiDAR return corresponding to the simulated object.

4. The system of claim 2, wherein the one or more processors are configured to:
determine that the number of LiDAR returns is one based on the comparison between the probability and the target number, wherein the simulated LiDAR perception data includes a single LiDAR return corresponding to the simulated at least partially transparent surface.

5. The system of claim 2, wherein the one or more processors are configured to:
determine that the number of LiDAR returns is one based on the comparison between the probability and the target number, wherein the simulated LiDAR perception data includes a single LiDAR return corresponding to the simulated object.

6. The system of claim 2, wherein the number of LiDAR returns is zero when a distance between the simulated object and the simulated at least partially transparent surface exceeds a distance threshold value.

7. The system of claim 1, wherein the one or more processors are configured to:
determine an absence of a simulated object that is positioned behind the simulated at least partially transparent surface; and
provide the angle of incidence to a piecewise linear function model to determine the probability.

8. The system of claim 7, wherein the one or more processors are configured to:
determine that the number of LiDAR returns is zero based on the comparison between the probability and the target number.

9. The system of claim 7, wherein the one or more processors are configured to:
determine that the number of LiDAR returns is one based on the comparison between the probability and the target number, wherein the simulated LiDAR perception data includes a single LiDAR return corresponding to the simulated at least partially transparent surface.

10. The system of claim 1, wherein the target number is randomly selected based on a uniform distribution.

11. The system of claim 1, wherein the target number is selected based on a simulation identifier associated with the simulated at least partially transparent surface.

12. The system of claim 1, wherein the target number is a weighted value based on a uniform distribution and a simulation identifier associated with the simulated at least partially transparent surface.

13. A method comprising:
receiving, within a simulation environment for a Light Detection and Ranging (LiDAR) sensor, an angle of incidence that is formed between a simulated transmission from a simulated LiDAR sensor and a simulated at least partially transparent surface;
determining, based on the angle of incidence, a probability of detecting at least one LiDAR return corresponding to a reflection of the simulated transmission from the simulated at least partially transparent surface; and
generating simulated LiDAR perception data corresponding to the reflection of the simulated transmission from the simulated at least partially transparent surface based on a comparison between the probability and a target number, wherein the simulated LiDAR perception data includes a number of LiDAR returns.

14. The method of claim 13, further comprising:
identifying a simulated object that is positioned behind the simulated at least partially transparent surface; and
providing the angle of incidence to a decreasing linear function model to determine the probability.

15. The method of claim 14, further comprising:
determining that the number of LiDAR returns is two based on the comparison between the probability and the target number, wherein the simulated LiDAR perception data includes a first LiDAR return corresponding to the simulated at least partially transparent surface and a second LiDAR return corresponding to the simulated object.

16. The method of claim 14, further comprising:
determining that the number of LiDAR returns is one based on the comparison between the probability and the target number, wherein the simulated LiDAR perception data includes either a single LiDAR return corresponding to the simulated at least partially transparent surface or a single LiDAR return corresponding to the simulated object.

17. The method of claim 14, wherein the number of LiDAR returns is zero when a distance between the simulated object and the simulated at least partially transparent surface exceeds a distance threshold value.

18. The method of claim 13, further comprising:
determining an absence of a simulated object that is positioned behind the simulated at least partially transparent surface; and
providing the angle of incidence to a piecewise linear function model to determine the probability.

19. The method of claim 13, the target number is selected based on at least one of a uniform distribution, a simulation identifier associated with the simulated at least partially transparent surface, and a combination thereof.

20. A non-transitory computer-readable storage medium comprising at least one instruction for causing a computer or processor to:
receive, within a simulation environment for a Light Detection and Ranging (LiDAR) sensor, an angle of incidence that is formed between a simulated transmission from a simulated LiDAR sensor and a simulated at least partially transparent surface;
determine, based on the angle of incidence, a probability of detecting at least one LiDAR return corresponding to a reflection of the simulated transmission from the simulated at least partially transparent surface; and
generate simulated LiDAR perception data corresponding to the reflection of the simulated transmission from the simulated at least partially transparent surface based on a comparison between the probability and a target number, wherein the simulated LiDAR perception data includes a number of LiDAR returns.
